(19) United States
(12) Patent Application Publication
(10) Pub. No.: US 2014/0127519 A1
(43) Pub. Date: May 8, 2014

(54) HIGH POWER IMPULSE MAGNETRON SPUTTERING METHOD PROVIDING ENHANCED IONIZATION OF THE SPUTTERED PARTICLES AND APPARATUS FOR ITS IMPLEMENTATION

(71) Applicant: Markus Lechthaler, Feldkirch (AT)

(72) Inventor: Markus Lechthaler, Feldkirch (AT)

(73) Assignee: OERLIKON TRADING AG, TRÜBBACH, Trubbach (CH)

(21) Appl. No.: 14/112,257

(22) PCT Filed: Apr. 16, 2012
(86) PCT No.: PCT/EP2012/001632

§ 371 Date: Jan. 22, 2014

Related U.S. Application Data
(60) Provisional application No. 61/477,216, filed on Apr. 20, 2011.

(51) Int. Cl. C23C 14/35; B23B 51/00

(52) U.S. Cl. CPC C23C 14/354; B23B 51/00
USPC 428/457; 204/192.12; 204/192.15; 204/298.08; 407/32; 428/698; 423/351; 423/411; 423/412

(57) ABSTRACT

Method for performing a HIPIMS coating process, whereby a minimal distance 5 between target and substrate is reduced till achieving an essentially maximal bias current at substrate during coating process, and thereby improving considerably coating quality and increasing deposition rate in comparison with conventional HIPIMS coating processes.

The present invention relates to a method to accomplish optimized high power impulse magnetron sputtering (HIPIMS) processes which exhibit enhanced ionization of the sputtered particles, higher coating deposition rates and enhanced coating quality in comparison to conventional HIPIMS coatings.

### STATE OF THE ART

Physical vapor deposition (PVD) processes are widely established as coating deposition processes for the manufacture of thin films used to protect tools and components and to enhance their original properties. There are different variants of PVD processes.

Very interesting PVD processes for coating of tools and components are for example arc ion plating (AIP) and magnetron sputter ion plating (MSIP) and anodic evaporation, which have corresponding advantages and disadvantages as for example following:
AIP is a really widely established technology. It is especially used for coating of cutting tools because of the exceptional very good quality of the coatings produced by means of it, regarding for example density, adhesion, hardness and cutting performance. Very advantageous are also the process conditions commonly obtained by AIP processes, regarding for example high plasma ionization, high coating deposition rates. Because of suitability and flexibility the AIP technology allows furthermore the synthesis of complex coating components and coating architectures from electro-conductive material targets. However, a fundamental disadvantage of AIP processes is the generation of droplets (not totally evaporated and not completely with reactive gas reacted macro particles from target) which can result in coating defects, unfavorable high coating roughness and unfavorable lower coating hardness.
MSIP is also a widely established technology that is especially use for coating of components, its most important advantage in comparison to the AIP technology is the possibility to avoid the formation of unfavorable droplets by coating process. However the coating quality of MSIP coatings (regarding coating density, coating adhesion and hardness) is generally inferior to the corresponding quality of AIP coatings. Additionally the plasma ionization in MSIP processes is also very poor and coating deposition rates attained by means of MSIP techniques are considerably lower than those obtained by means of AIP techniques.
Anodic evaporation is a very interesting coating deposition technology that allows the production of high quality coatings deposited by high deposition rates and without droplets. However, this technology doesn't offer flexibility concerning synthesis of complex coating components but only simple coating components such as TiN, CrN and TiCN have been until now synthetized using anodic evaporation techniques.

HIPIMS technology on its part has gained much interest in the last years, especially to be used for coating of components and tools. HIPIMS is a PVD sputtering technology which allows the generation of low pressure plasmas having considerably higher metal particles ionization than plasmas generated by MSIP techniques. Hence, the HIPIMS technology allows the synthesis of smooth coatings without droplets (similarly as coatings deposited by means of MSIP techniques) but exhibiting considerably higher coating quality (e.g. concerning coating density and hardness) than coatings synthetized using MSIP techniques.

The higher plasma densities obtained by HIPIMS processes in comparison to MSIP processes are generated by increasing the power dissipated in the discharge which allows attaining high current densities of about 4-5 A/cm² and consequently high plasma densities in the order of 10¹³ cm⁻³. Hence, the sputtered metal particles ejected from the target have high probability of ionization.

However, in spite of the very interesting advantages offered by HIPIMS technology, the very low coating deposition rates (lower than MSIP coating deposition rates) observed by coating deposition using this technology resulting in a big disadvantage considering efficiency.

Similarly as by MSIP processes, also by HIPIMS processes specific shaped magnetic fields are required, these fields are used to trap and confine a significant part of the plasma near to the target surface and so to attain high discharge currents. These magnetic fields are configured so that electrons are trapped in the vicinity of the target and follow a helical motion, in this way, their path length is increased in the given volume and the probability of ionizing the working gas and sputtered metals particles is also increased. The strength of the magnetic field determines the degree of confinement and therefore stronger magnetic fields decrease the impedance of the discharge and allow higher discharge currents to be obtained by the same target voltage.

In GB2437730 it is mentioned that the very low deposition rates observed by HIPIMS processes can be directly related to the high ionization of the sputtered material near the target surface. According to GB2437730 it is supposed that a large fraction of the ions generated by ionization of the sputtered material go back towards the sputtering target because of the action of the electric field at the cathodes and thus these ions become unavailable for coating deposition. Furthermore GB2437730 discloses a modified HIPIMS PVD process and a corresponding apparatus which allow that the ions generated from the material target are less strongly confined by the magnetic field within the region of the target whereby such ions may more readily escape from the magnetic confinement to be deposited on the substrate surface and thus the coating deposition rate can be increased.

### LIMITATIONS OF THE STATE OF THE ART USING THE HIPIMS TECHNOLOGY

In spite of using more suitable magnetic fields by HIPIMS processes, it have been observed that the used magnetic fields and the consequently resulting load plasma conditions can hinder the propagation of the metal ions within the plasma in such a manner that depositing homogeneous high quality coatings on large surface substrates can be difficult.

In spite of the possibility of generating plasmas containing a high quantity of metal ions by means of HIPIMS techniques, the coating quality of coatings deposited by HIPIMS processes continues being in general inferior (regarding for example coating density, hardness and cutting performance) than the corresponding coating quality of coatings deposited by AIP processes (excepting certainly smoothing properties).

### OBJECTIVE OF THE INVENTION

It is an objective of the present invention to provide a method to optimize HIPIMS processes in order to accomplish HIPIMS processes that allow deposition of high quality HIPIMS coatings on large surface substrates, preferably providing at the same time enhanced coating qualities and higher deposition rates compared to conventional HIPIMS processes or HIPIMS processes currently considered state of the art.

### DESCRIPTION OF THE INVENTION

The inventor assumed that the homogeneity of coatings could depend on the distance between cathode and substrate surface. Therefore, in order to deposit homogeneous coatings along large surface substrates by using HIPIMS techniques, the inventor carried out several HIPIMS coating processes which were accomplished after adjusting different distances between cathode (more specifically target surface) and substrate surface. During coating process typically the substrates are in movement and passing the cathode at a distance which is defined in the context of this specification as minimal distance 5. In other words the shortest distance between cathode surface and substrate surface during coating process will be defined and referred to as minimal distance 5, as it is outlined in FIGS. 1a-b.

The synthetized coatings were analyzed. The HIPIMS coatings deposited after adjusting a “determined” minimal distance 5 exhibited surprisingly a considerably higher coating quality (especially concerning coating density and mechanical properties such as coating hardness) compared to all other HIPIMS coatings which were synthetized by using other different minimal distances 5. Furthermore, the deposition rate of the coating synthetized at the above mentioned “determined” minimal distance 5 was considerably higher than the others.

For the purpose of understand this phenomenon the inventor analyzed the effect of the minimal distance 5 on the process characteristics and more specifically on the plasma properties by HIPIMS processes. The analyses were realized by reducing systematically step by step the minimal distance 5 (reducing the minimal distance between target surface and substrate surface approximately 0.5 cm by each step).

The bias current at substrate was continuously measured during this systematical reduction of the minimal distance.

It was observed that the bias current measured at substrate surprisingly jumped to higher values when a “special minimal distance” was achieved. This “special minimal distance” coincided with the “determined” minimal distance 5 at which HIPIMS coatings could be synthetized with an unexpectedly higher deposition rate and a considerably higher coating quality.

The inventor observed also that trying to adjust a minimal distance 5 smaller than the “determined” minimal distance 5 both deposition rate and coating quality became inferior. This could be due to instabilities of the plasma with such distances. The minimal distance that has been referred to as “determined” minimal distance until now, will be within the present invention subsequently referred to as “optimized” minimal distance. Therefore, the term “optimized” minimal distance 5 within the present invention refers to the minimal distance 5, at which an essentially maximal bias current at substrate can be achieved by a HIPIMS coating deposition process without to generate plasma instabilities.

The inventor supposes that by adjusting the “optimized” minimal distance 5 according to the present invention, at which the bias current at substrate during HIPIMS coating process can essentially be maximized, the quantity of metal ions which arrive at the substrate can be likewise maximized. Thereby the deposition rate is increased and the coating quality is improved.

For the evaluation of the cutting performance of the HIPIMS coatings synthetized according to the present invention, cutting tools were coated with HIPIMS coatings according to the present invention as well as with analogous AIP and MSIP coatings. In order to do a fair comparison as possible the analogous AIP and MSIP coatings were deposited having a nearly similar coating architecture and composition to the HIPIMS coatings synthetized according to the present invention. The AIP coatings were additionally post-treated after coating with the purpose of removing droplets and consequently reducing roughness and improving surface quality. (see results in cutting test 1 described below).

Concerning cutting performance the HIPIMS coatings synthetized according to the present invention exhibited a very similar cutting performance to the analogous AIP-coatings in cutting tests. Likewise, the superior cutting performance of the HIPIMS coating synthetized according to the present invention in comparison to analogous MSIP coatings was confirmed by cutting tests (see results in cutting test 2 described below).

According to these results, HIPIMS coatings synthetized according to the present invention could exhibit a better cutting performance than AIP coatings without post-treatment for removing droplets. Moreover, the use of HIPIMS coatings could allow reducing costs generated by post-treatments for removing droplets.

The inventor has observed that the nowadays standardized industrial HIPIMS coating machines possess typical minimal distances between target surface and substrate surface of about 15-8 cm doesn't correspond with a range of optimized minimal distances. But according to the present invention, an optimized minimal distance 5 should be preferably shorter. For example, in the case of a coating process for the deposition of titanium aluminum nitride (TiAlN) coatings using HIPIMS techniques, the range of optimized minimal distances 5 according to the present invention was found to be about 5-3 cm. Also, particularly by the deposition of TiAlN coatings, the inventor observed repeatedly that plasma instabilities are generated when minimal distances 5 shorter than 3 cm are used.

An embodiment of the present invention is a coating machine similar as the coating machine exemplary drafted in FIG. 1 using 2-4 cathodes and arranged so that the adjusted minimal distance 5 between target surface and substrate surface is the optimized minimal distance according to the present invention. According to the invention the minimal distance 5 between target surface and substrate surface will be thereby optimized when the bias current at substrate is maximized. With this intention the minimal distance 5 should be maintained as short as possible but avoiding generation of plasma instabilities.

An embodiment of the present invention is a HIPIMS coating machine where the HIPIMS cathode or HIPIMS cathodes is/are mounted to a connection or intermediate flange of the coating chamber in the HIPIMS coating machine and the connection or intermediate flange is constructed in such a manner that the flange allows the necessary cathode mobility in order to adjust the minimum distance between cathode and substrate to the “optimized” minimal distance. This embodiment of the invention is particularly favorable when complex geometries are to be coated according the invention.

A further embodiment of the invention involves a method to realize automation of a HIPIMS coating machine in order to execute HIPIMS coating processes by maximal bias current according to the invention. According to this embodiment of the present invention the mobility mechanism of the cathode position in relation to the substrate surface is regulated by a control system that includes a sensor for measuring bias current at substrate. Furthermore, according to the present embodiment the control system adjust the minimal distance 5 between target surface at cathode and substrate surface automatically and systematically until the “optimized” minimal distance is attained. The “optimized” minimal distance is achieved when the maximal bias current by stable process plasma conditions is attained. According to the observations of the inventor it occurs when by reducing the minimal distance 5 between target surface and substrate surface a jump in the bias current measured at substrate is detected, which can be about 40% according to the observations of the inventor.

Moreover the present invention provides a method for optimizing HIPIMS processes independent of coating arrangement, target materials, process gas, magnetic fields, substrate geometry and dimension, dimension of HIPIMS coating machine and components, further process parameters, etc.

The present invention can be especially used for synthesis of wear resistance hard coatings, which content at least one element of groups IVb, Vb, VIb, aluminum (Al), silicon (Si) and boron (B), and at least one nonmetallic element such as carbon (C), nitrogen (N) and oxygen (O).

Furthermore, the present invention is especially suitable for deposition of TiAlN coatings on coating tools. TiAlN synthetized according to the invention exhibited outstanding good cutting performance, which was comparable to the cutting performance of analogous TiAlN synthetized using AIP techniques and post-treated in order to eliminate droplets on the coating surface. According to the obtained results by cutting tests, the present invention provides also a considerably high economical advantage in comparison to using post-treated AIP coatings for cutting operations. This is a consequence of the fact that by using HIPIMS coatings synthetized according to the invention it is possible to attain comparable cutting performances but avoiding the usually necessary droplet removal post-treatments in AIP coatings which are normally expensive and time-consuming.

Furthermore the present invention allows improvement of tool performance in coated micro tools, whose surface quality cannot be improved by accomplishing droplet removal post-treatments because of their geometric characteristics (e.g. micro tools having diameters in range of 1 mm or less).

### Accomplished Cutting Tests:

Cutting Test 1:

Cutting tests carried out in order to compare the cutting performance of the HIPIMS coatings synthetized according to the invention and conventional HIPIMS coatings:

Work piece: DIN 1.2344 (52 HRC)

Cutting tool: 2-flute ball nose end drill, φ 10 mm, fine grained cemented carbide

Cutting velocity: 314 m/min

Pitch: 0.4 mm/feed rate

Radial feed: 0.5 mm

Axial feed: 0.3 mm

Cooling medium: wet machining 6% emulsion

Milling strategy: lateral milling

Wear criterion: V_{bmax}>100 μm as well as coating delamination at chisel edge

Result (maximal endurance of tested coated tools):
AIP TiAlN coatings with additional droplets removing post-treatment after coating (and having analogous coating composition and architecture): 80 m
HIPIMS TIAlN coatings synthetized according to the invention: 80 m

Cutting Test 2:

Cutting tests carried out in order to compare the cutting performance of the HIPIMS coatings synthetized according to the invention and conventional HIPIMS coatings:

Work piece: DIN 1191 (180 HB)

Cutting tool: 3-flute end mill, φ 8 mm, fine grained cemented carbide

Cutting velocity: 290 m/min

Pitch: 0.01 mm/feed rate

Radial feed: 0.5 mm

Axial feed: 10 mm

Cooling medium: wet machining 6% emulsion

Milling strategy: lateral milling

Wear criterion: V_{bmax}>120 μm

Result (maximal endurance of testes coated tools):
MSIP TiAlN coatings (and having analogous coating composition and architecture): 30 m
HIPIMS TIAlN coatings synthetized according to the invention: 75 m

### EXAMPLE OF THE PRESENT INVENTION

Different HIPIMS processes were accomplished at an industrial HIPIMS coating machine such as this drafted in FIG. 1 and the process parameters were configured setting as following:
Gas flow: Ar=200 sccm, N₂=100 sccm
Cathode power: 15 kW
Target material: alloyed Ti—Al
Pulse duration: 200 μs
Pulse frequency: 500 Hz

The minimal distance 5 was reduced systematically step by step and bias current at substrate was measured and registered. The observed behavior is reported in FIG. 5. By reducing the minimal distance 5 between cathode and substrate the bias current increase very slowly till a “determined” minimal distance (about 5 cm by this experiment) was attained. Within the present invention this distance between cathode and substrate by it the bias current jump was detected will be called “optimized minimal distance”. After the jump only a very light variation of the bias current was observed till a critical “minimal distance” (about 3 cm by this experiment) was achieved by it process plasma conditions turned instable and a bias current signal as this showed in FIG. 4 was observed.

This example may show the method used to maximize bias current adjusting an “optimized” minimal distance between cathode and substrate according to the present invention in order to accomplish enhanced or optimized HIPIMS processes. The inventor advert that the “optimized” minimal distance can depend of different process parameters like for example process pressure, magnetic fields, coating machine dimensions, etc.

It is to be understood that this disclosure is not limited to the observations resulted from the particular experiments that were investigated.

A preferred embodiment of the present invention is a method for optimizing HIPIMS coating processes, wherein the bias current measured at substrate is maximized.

A further preferred embodiment of the present invention is a is a method for optimizing HIPIMS coating processes, wherein the bias current measured at substrate is maximized, wherein the minimal distance 5 between target surface fixed at cathode and substrate surface is systematically reduced till attaining the “optimized” minimal distance at which the bias current measured at substrate is maximal and process plasma conditions are stable.

A further preferred embodiment of the present invention is an optimized HIPIMS process, wherein bias current has been maximized according to one of the methods that were described previously.

A further preferred embodiment of the present invention is an optimized HIPIMS process as it described above, wherein the minimal distance 5 between cathode and substrate during process is adjusted automatically.

A further preferred embodiment of the present invention is an optimized HIPIMS process as these, which were described above, wherein the coating produced by means of the HIPIMS process comprises titanium, aluminium and nitrogen.

A further preferred embodiment of the present invention is an optimized HIPIMS process as these, which were described above, wherein the coating produced by means of the HIPIMS process consists of TiAlN or contains at least one TiAlN layer.

A further preferred embodiment of the present invention includes also the apparatus for the execution of the optimized HIPIMS processes described above.

Every kind of substrates or bodies can be coated or at least partially coated by means of the optimized HIPIMS processes performed according to the present invention as described before. Especially substrates/bodies having a large surface to be coated or partially coated can be coated more homogeneously.

The substrates to be coated or partially coated according to the present invention can be tools as well as components.

The performance of cutting tools, forming tools, components of engines, automobiles components or turbines components can be enhanced applying coatings produced according to the present invention.

### DESCRIPTION OF THE FIGURES

FIG. 1: Draft of HIPIMS coating machines which can be used to accomplish HIPIMS processes according to the invention. The coating machines drafted in FIGS. 1a and 1b shows two exemplary coating arrangements having:
1: Cathodes with material source targets
2: Carrousel with substrates to be coated
3: Etching sources
4: Heaters
5: Minimal distance between cathode (more exactly target surface) and substrate surface FIG. 2: Photo of the developing of the bias current and cathode current signals measured at different minimal distances 5 of approximately 6 cm and 3.5 cm±0.5 cm respectively. Further process parameters concerning gas flow, cathode power, target material, pulse duration and pulse frequency were the same than those that were used in the example 1 described before.

FIG. 3: Photo of the developing of the bias current, cathode current and cathode voltage measured at different minimal distances 5 of approximately 10 cm, 6 cm and 4 cm±0.5 cm respectively. Further process parameters concerning gas flow, cathode power, target material, pulse duration and pulse frequency were the same than those that were used in the example 1 described before.

FIG. 4: Photo of the developing of the bias current and cathode current signals measured at a minimal distance of approximately 2.5 cm. The measured current signals observed in FIG. 4a and FIG. 4b (magnification) show clearly that adjusting a too short distance between target surface and substrate surface, the plasma conditions become instable. This phenomenon can be observed in the signal instabilities of both cathode current and bias current. The inventor observed this phenomenon repeatedly when minimal distances 5 of about 3 cm and shorter were adjusted by coating process. Further process parameters concerning gas flow, cathode power, target material, pulse duration and pulse frequency were the same than those that were used in the example 1 described before.

FIG. 5a: Developing of bias current measured at substrate by reducing minimal distance between target surface at cathode and substrate surface. Bias current increases by reducing minimal distance 5 and surprisingly jumped by a “determined” minimal distance of about 5 cm than within the present invention will be also called “optimized” minimal distance between cathode and substrate.

The case displayed in FIGS. 5a and 5b is only an example of the present invention and the inventor advert that the “optimized” minimal distance can be dependent of other different process parameters like for example process pressure, magnetic fields, etc.

FIG. 5b: Same developing of bias current measured at substrate by reducing minimal distance 5 between target surface at cathode and substrate surface as it is displayed in FIG. 5a, showing four different ranges of minimal distances A, B, C and D. The range A of minimal distances is characterized by minimal distances 5 at which the bias current measured at substrate seems to remain constant or increases very slowly by reducing minimal distance and the process plasma conditions remain stable, such range in the following being referred to as the A-range. The range B of minimal distances is characterized by minimal distances 5 next to the A-range at which the bias current measured at substrate increases very quickly (the curve minimal distance in centimeters vs. bias current in amperes describes a pronounced slope or jump) by reducing minimal distance and the process plasma conditions remain stable. Such range in the following being referred to as B-range. The range C next to the B-range of minimal distances is defined and characterized by minimal distances 5 at which the bias current measured at substrate increases forward but only very slowly until achieving a maximal value. The range D, following the C-range of minimal distances is characterized by minimal distances 5 at which the bias current measured at substrate decreases and within the D-range the process plasma conditions become instable. It is noted that the for the minimal distances dₘᵢₙ the following holds: dₘᵢₙ(A-range)>dₘᵢₙ(B-range)>dₘᵢₙ(C-range)>Dₘᵢₙ(D-range).

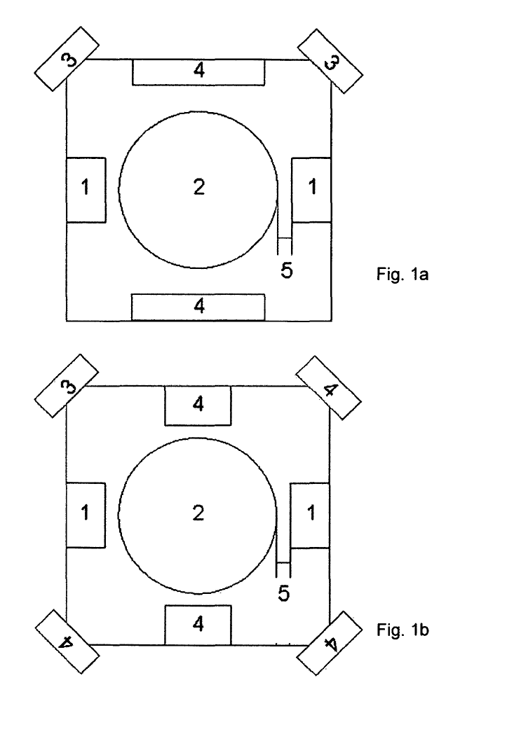

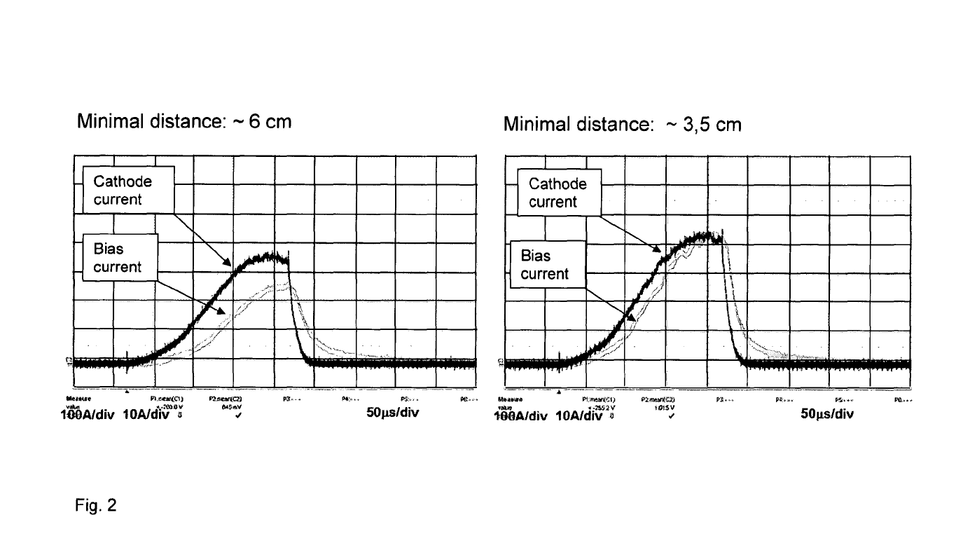

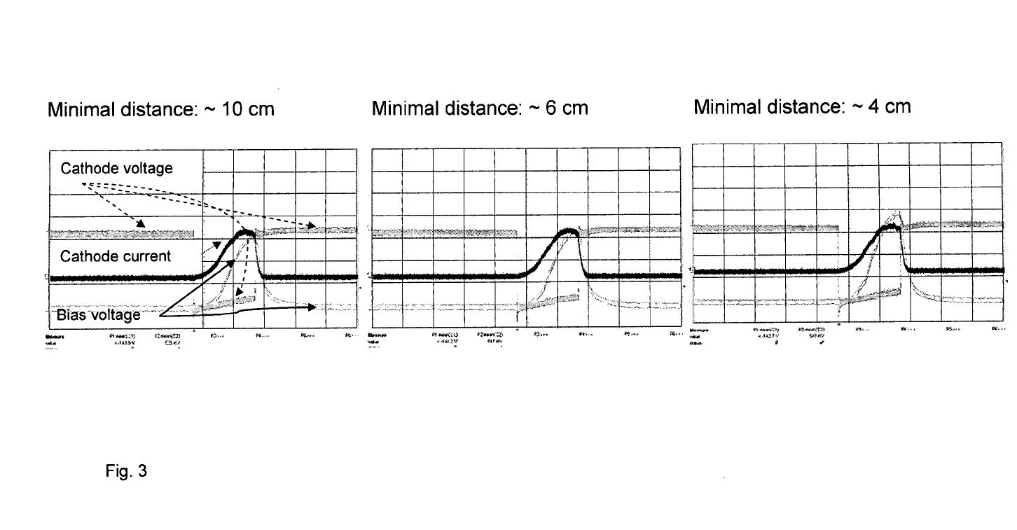

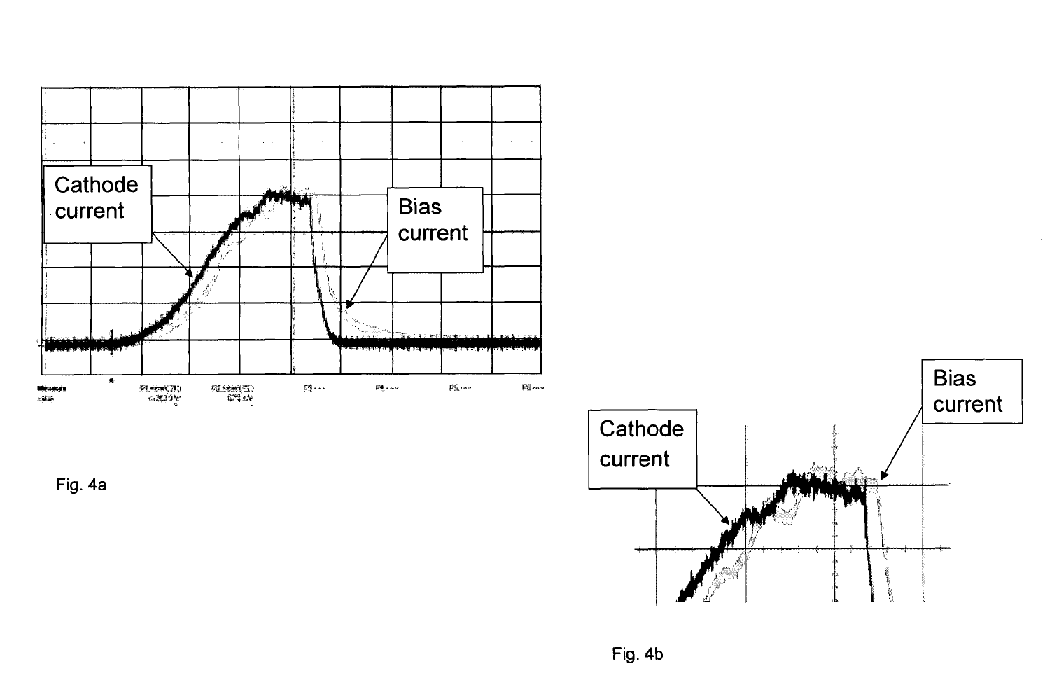

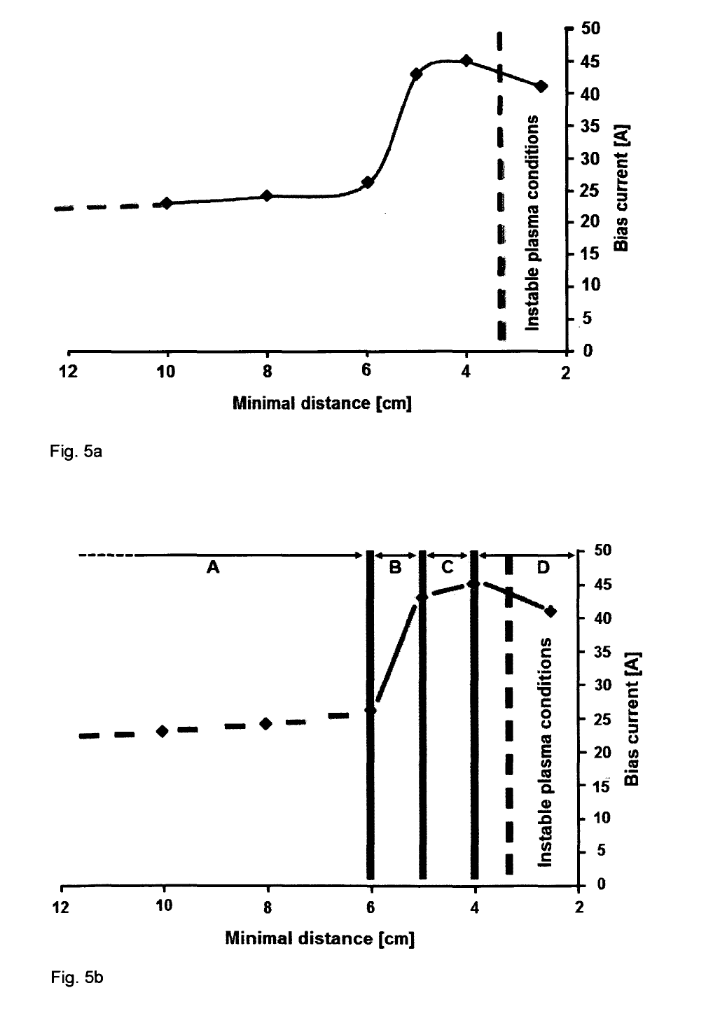

What is claimed is:

1. Method for performing a HIPIMS coating process comprising the following steps:
Arranging at least one substrate having a surface to be coated in the interior of a coating chamber of a coating device, the coating device comprising at least a target which is a coating material source to be operated during coating process by means of HIPIMS technology, arranging the substrate in such a manner, that the surface to be coated can be positioned in front of the target during at least some time during coating process
Operating the HIPIMS coating device in order to coat the at least one substrate, thereby applying a bias voltage to the substrate during the coating process and thus generating a bias current that can be measured at the substrate,
characterized in that,
the minimal distance (5) between the substrate and the target, which is given when the surface to be coated is closest to the target, is adjusted to attain an optimized minimal distance in such a way that the bias current, if measured at the substrate during coating, attains essentially a maximal value while the process plasma conditions remain stable.

2. Method according to claim 1, characterized in that, for attaining the optimized minimal distance the bias current is measured at the substrate while, starting with a minimal distance within the A-range the minimal distance (5) between the substrate and the target is continuously or stepwise reduced until reaching a minimal distance (5) smaller than distances within the B-range which are closer to the C-range than to the A-range.

3. Method according to claim 2, characterized in that, the minimal distance (5) between the substrate and the target is continuously or stepwise reduced until reaching a minimal distance (5) smaller than distances within the 8-range.

4. Method according to claim 3, characterized in that, the minimal distance (5) between the substrate and the target is continuously or stepwise reduced until reaching a minimal distance (5) essentially within the C-range, preferably closer to the B-range as to the D-range.

5. Method according to claim 3, characterized in that, the minimal distance (5) between the substrate and the target is continuously or stepwise reduced until reaching a minimal distance (5) essentially within the D-range, closer to the C-range as to the portion of the D-range comprising distances at which the process plasma conditions are instable.

6. Method according to claim 2, characterized in that, for adjusting the optimized minimal distance a mobility mechanism is used for varying the target position in relation to the substrate surface and thus varying the minimal distance (5) till attaining the optimized minimal distance automatically.

7. Method according to claim 6, characterized in that, the action of the mobility mechanism is regulated by a control system that includes a sensor for measuring bias current at substrate, and the control system varies the minimal distance 5 systematically till a maximum value of the measured bias current is achieved and thus the coating optimized minimal distance for accomplishing the coating process is attained.

8. HIPIMS coating process characterized in that, a minimal distance 5 between target and substrate during coating deposition is optimized using a method according to at least one of the anterior claims.

9. HIPIMS coating process according to claim 8, characterized in that, the optimized minimal distance is adjusted automatically before or by coating process beginning.

10. HIPIMS coating process according to claim 1, characterized in that, the coating produced
comprises titanium and/or aluminum and/or nitrogen, or
consists of titanium aluminum nitride, or
comprises at least one titanium aluminum nitride layer.

11. Apparatus for execution of a HIPIMS coating process according to claim 1.

12. Body at least partially coated by using a HIPIMS coating process according to claim 1.

13. Body coated according to claim 12, characterized in that, the body is a tool for machining operations such as a cutting tool or a forming tool, preferably a micro drill.

14. Body coated according to claim 12, characterized in that, the body is a component such as an engine component or an automobile component or a turbine component.

15. Use of a coated body according to claim 12 in tribological systems.
